(19) United States
(12) Patent Application Publication
(10) Pub. No.: US 2016/0035584 A1
(43) Pub. Date: Feb. 4, 2016

(54) PLANARIZATION METHOD, SUBSTRATE TREATMENT SYSTEM, MRAM MANUFACTURING METHOD, AND MRAM ELEMENT

(71) Applicants: TOKYO ELECTRON LIMITED, Tokyo (JP); UNIVERSITY OF HYOGO, Kobe-shi (JP)

(72) Inventors: Kenichi HARA, Nirasaki City (JP); Noriaki TOYODA, Kobe-shi (JP); Isao YAMADA, Kobe-shi (JP)

(21) Appl. No.: 14/845,617

(22) Filed: Sep. 4, 2015

Related U.S. Application Data
(63) Continuation of application No. PCT/JP2014/055703, filed on Feb. 27, 2014.

(30) Foreign Application Priority Data
Mar. 7, 2013 (JP) 2013-045261

(51) Int. Cl. H01L 21/321; H01L 43/12; H01L 43/02

(52) U.S. Cl. CPC H01L 21/32115; H01L 43/02; H01L 43/12

(57) ABSTRACT

Provided is a planarization method capable of reliably planarizing a metal film formed before an MTJ element of an MRAM is formed. An MTJ element is formed by a sequence of processes including: forming a Cu film to be embedded in a SiO₂ film in a wafer W; irradiating an oxygen GCIB to a surface of the Cu film to planarize the Cu film; forming a Ta film; forming a Ru film or a Ta film; irradiating the oxygen GCIB to the Ta film, the Ru film or the Ta film to planarize the Ta film, the Ru film or the Ta film; forming a PtMn film; irradiating the oxygen GCIB to a surface of the PtMn film to planarize the PtMn film; forming a CoFe thin film and a Ru thin film; and forming a CoFeB thin film, a MgO thin film and a CoFeB thin film in that order.

### CROSS-REFERENCE TO RELATED APPLICATION

This application is a Continuation Application of PCT International Application No. PCT/JP2014/055703, filed Feb. 27, 2014, which claimed the benefit of Japanese Patent Application No. 2013-045261, filed on Mar. 7, 2013, the entire contents of which are incorporated by reference herein.

### TECHNICAL FIELD

The present disclosure relates to a planarization method of planarizing a metal film formed before an MTJ element of an MRAM is formed, a substrate treatment system, an MRAM manufacturing method, and the MRAM element.

### BACKGROUND

In recent years, MRAM (Magnetoresistive Random Access Memory) has been developed as a next-generation nonvolatile memory in lieu of DRAM or SPRAM. MRAM includes an MTJ (Magnetic Tunnel Junction) element instead of a capacitor and stores data using magnetization states.

The MTJ element is configured by an insulating film, e.g., an MgO film, and two ferromagnetic films, e.g., CoFeB films, which are formed to face each other with the MgO film interposed therebetween. In this case, if the MgO film is not planarized, an undesirable effect such as a decrease in an MR ratio (Magneto-Resistance ratio) may be exerted on a property of the MTJ element.

In FIG. 16, an MTJ element 100 is formed on a metal film 104. MgO film 102 and CoFeB films 101 and 103 all have an extremely thin thickness so that they are influenced by irregularities formed on a surface of the metal film 104, which results in a degraded flatness.

In order to improve such flatness, a planarization method using a GCIB (Gas Cluster Ion Beam) is known as a plasma-less planarization method.

The GCIB is a technique which includes: spraying a gas toward a vacuum atmosphere to form a cluster of molecules constituting the gas; ionizing the cluster; and accelerating the ionized cluster by a bias voltage to collide the ionized cluster with a wafer.

The cluster is known to have a lateral sputtering effect in which, when the cluster collides with a metal film or the like, molecules are scattered from the cluster along a surface of the metal film such that convex portions protruding from the surface are preferentially sputtered.

A rare gas (e.g., an argon (Ar) gas) having a large atomic weight is used in planarizing the metal film 104 with the GCIB.

However, the metal film 104 is often made of a noble metal that is hard to etch. As such, even if an argon gas having a large atomic weight is used in the GCIB, it is still difficult to sputter and etch the convex portions of the metal film 104. Thus, it is difficult to reliably planarize the metal film 104.

### SUMMARY

Embodiments of the present disclosure provide a planarization method of reliably planarizing a metal film formed before an MTJ element of an MRAM is formed, a substrate treatment system, an MRAM manufacturing method, and the MRAM element.

In one embodiment, a planarization method includes irradiating an oxygen GCIB to a metal film formed on a substrate, followed by forming an MTJ element of an MRAM.

The present disclosure also indicates that in some embodiments the oxygen GCIB is irradiated to the metal film in an organic acid atmosphere.

The present disclosure also indicates that in some embodiments the substrate is heated after the irradiation of the oxygen GCIB to the metal film.

The present disclosure also indicates that in some embodiments a plurality of metal films is formed on the substrate, followed by forming the MTJ element, wherein the oxygen GCIB is irradiated to one metal film after forming the one metal film of the plurality of metal films and before forming another metal film that covers the one metal film.

The present disclosure also indicates that in some embodiments the oxygen GCIB is irradiated to the metal film that is formed immediately before forming the MTJ element at least.

The present disclosure also indicates that in some embodiments the substrate is heated before the irradiation of the oxygen GCIB to the metal film.

In another embodiment, there is provided a substrate treatment system which includes a film-forming processing chamber configured to form a metal film and a GCIB irradiation processing chamber configured to irradiate an oxygen GCIB, wherein the film-forming processing chamber is configured to form the metal film on a substrate before an MTJ element of an MRAM is formed, and the GCIB irradiation processing chamber is configured to irradiate the oxygen GCIB to the formed metal film before forming the MTJ element.

The present disclosure indicates that in some embodiments the substrate treatment system further includes a heating processing chamber configured to heat the substrate, wherein the heating processing chamber heats the substrate after the formation of the metal film and before the irradiation of the oxygen GCIB to the metal film.

In another embodiment, there is provided an MRAM manufacturing method which includes: a lower electrode formation step of forming a lower electrode; a lower metal layer formation step of forming a lower metal layer on the lower electrode; an anti-ferromagnetic layer formation step of forming an anti-ferromagnetic layer on the lower metal layer; an MTJ element formation step of forming an MTJ element on the anti-ferromagnetic layer; and an upper electrode formation step of forming an upper electrode on the MTJ element. The MRAM manufacturing method further includes a planarization step that is performed at least one of: between the lower electrode formation step and the lower metal layer formation step, between the lower metal layer formation step and the anti-ferromagnetic layer formation step, and between the anti-ferromagnetic layer formation step and the MTJ element formation step, wherein the planarization step includes irradiating an oxygen GCIB to a formed metal film.

In another embodiment, there is provided an MRAM manufacturing method which includes: a lower electrode formation step of forming a lower electrode; a planarization step of planarizing the lower electrode; an MTJ element formation step of forming an MTJ element on the planarized lower electrode; an anti-ferromagnetic layer formation step of forming an anti-ferromagnetic layer on the MTJ element; an upper metal layer formation step of forming an upper metal layer on the anti-ferromagnetic layer; and an upper electrode formation step of forming an upper electrode on the upper metal layer, wherein the planarization step includes irradiating an oxygen GCIB to a formed metal film.

In another embodiment, there is provided an MRAM element including at least an MTJ element formed on a metal film, wherein a flatness of the metal film is Ra=1.0 nm or less.

According to the present disclosure, it is possible to reliably planarize a metal film that is formed before an MTJ element of an MRAM is formed.

### BRIEF DESCRIPTION OF THE DRAWINGS

FIG. 1 is a plan view schematically showing a configuration of a substrate treatment system according to a first embodiment of the present disclosure.

FIG. 2 is a cross-sectional view schematically showing a configuration of a planarization processing module of FIG. 1.

FIG. 3 is a cross-sectional view schematically showing a configuration of a GCIB irradiation device of FIG. 2.

FIG. 4 is a cross-sectional view explaining a planarization process performed by irradiating an oxygen GCIB.

FIG. 5 is a cross-sectional view schematically showing a configuration of an MRAM to which the planarization method according to one embodiment is applied.

FIG. 6 is a cross-sectional view showing a state in which irregularities formed on a Cu film are propagated to other metal films in a MRAM manufacturing process.

FIG. 7 is a cross-sectional view explaining a planarization process of a Cu film, which is performed by irradiating an oxygen GCIB.

FIG. 8 is a cross-sectional view showing a state in which irregularities formed on a Ta film are propagated to other metal films in the MRAM manufacturing process.

FIG. 9 is a cross-sectional view explaining a planarization process of a Ta film, which is performed by irradiating an oxygen GCIB.

FIG. 10 is a cross-sectional view showing a state in which irregularities formed on a PtMn film are propagated to other metal films in the MRAM manufacturing process.

FIG. 11 is a cross-sectional view explaining a planarization process of a PtMn film, which is performed by irradiating an oxygen GCIB.

FIG. 12 is a flowchart of an MRAM manufacturing process to which a planarization method according to one embodiment is applied.

FIG. 13 is a plan view schematically showing a configuration of a substrate treatment system according to a second embodiment of the present disclosure.

FIG. 14 is a flowchart of a planarization method according to another embodiment.

FIG. 15 is a flowchart of a modified example of a planarization method according to another embodiment.

FIG. 16 is a cross-sectional view schematically showing a general configuration of an MRAM.

### DETAILED DESCRIPTION

Hereinafter, some embodiments of the present disclosure will be described with reference to the drawings.

First, a substrate treatment system according to a first embodiment of the present disclosure will be described.

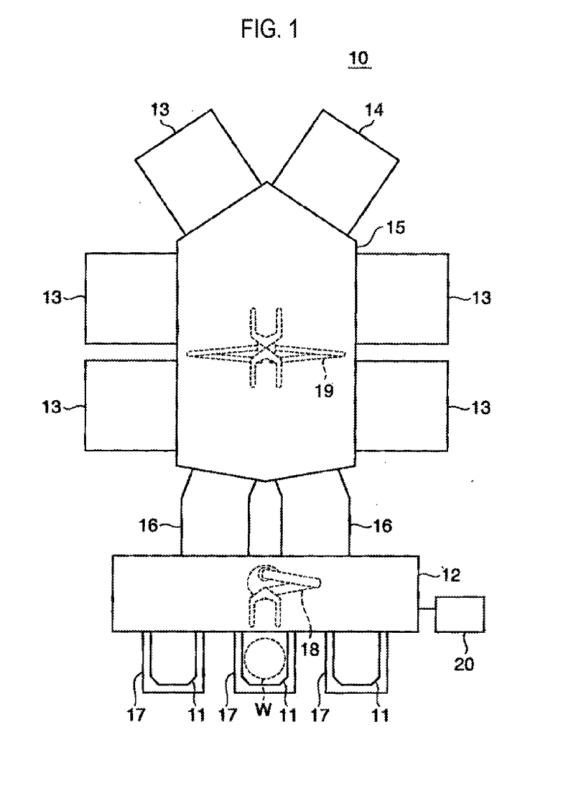

FIG. 1 is a plan view schematically showing a configuration of the substrate treatment system according to the first embodiment.

In FIG. 1, for example, a substrate treatment system 10 includes: a loader module 12 configured to unload a wafer W from respective vessels, e.g., FOUPs (Front Opening Unified Pods) 11 each of which accommodates a plurality of wafers W (indicated by a broken line in FIG. 1); a plurality of film-forming processing modules (or film-forming processing chambers) 13 configured to perform a film-forming process on the wafer W; a planarization processing module (or GCIB irradiation processing chamber) 14 configured to perform a planarization process (which will be described later) of FIG. 4 on the wafer W which is subjected to the film-forming process; a transfer module 15 configured to load or unload each of the wafers W into or from the respective film-forming processing module 13; and two load-lock modules 16 configured to deliver each of the wafers W between the loader module 12 and the transfer module 15.

The loader module 12 includes a transfer chamber whose interior is opened to an atmosphere, which has a substantially rectangular parallelepiped shape. The loader module 12 includes load ports 17 on each of which the FOUP 11 is mounted. The loader module 12 includes a transfer arm 18 (indicated by a broken line in FIG. 1) provided within the transfer chamber. The transfer arm 18 is configured to load or unload each of the wafers W into or from the FOUP 11 mounted on each of the load ports 17.

The plurality of film-forming processing modules 13 are connected to the transfer module 15 while being radially arranged around the transfer module 15. The transfer module 15 includes a transfer chamber whose interior is depressurized. A transfer arm 19 (indicated by a broken line in FIG. 1), which is disposed within the transfer chamber of the transfer module 15, transfers each of the wafers W between the respective film-forming processing modules 13, the planarization processing module 14 and the respective load-lock modules 16.

The load-lock module 16 includes a standby chamber whose interior can be defined to an atmospheric pressure environment or a depressurized environment. The transfer arm 18 of the loader module 12 and the transfer arm 19 of the transfer module 15 transfer each of the wafers W through the respective load-lock modules 16.

Each of the film-forming processing modules 13 includes a processing chamber whose interior is depressurized. Each of the film-forming processing modules 13 accommodates a single wafer W into the respective processing chamber, and performs a film-forming process on the single wafer W by sputtering plasma generated in the respective processing chamber.

The substrate treatment system 10 includes a control part 20. The control part 20 controls operations of respective components of the substrate treatment system 10 according to, e.g., a program configured to execute a desired recipe, such that a process corresponding to the desired recipe is performed on each of the wafers W. While in FIG. 1, the control part 20 is shown to be connected to the loader module 12, the control part 20 may be connected to any one of the respective components of the substrate treatment system 10. Alternatively, the control part 20 may be included in any one of the respective components. Further, the control part 20 may be configured as an external server which is installed in a location differing from a location in which the substrate treatment system 10 is installed.

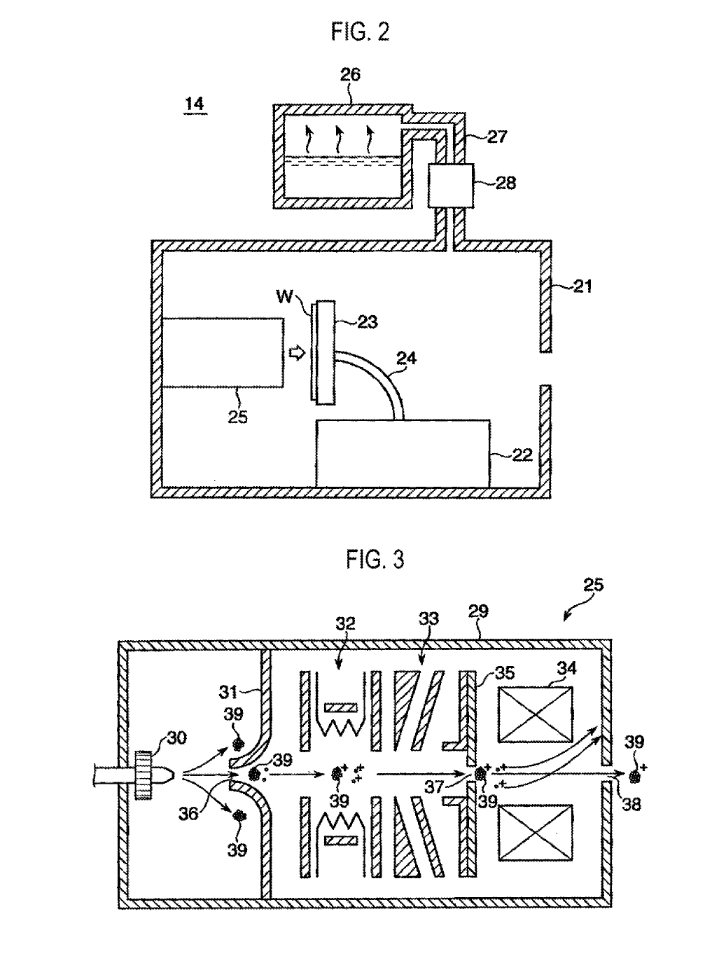

FIG. 2 is a cross-sectional view schematically showing a configuration of the planarization processing module 14 of FIG. 1.

In FIG. 2, the planarization processing module 14 includes: a processing chamber 21 configured to accommodate the wafer W; a mounting table 22 disposed in a lower portion of the processing chamber 21; an electrostatic chuck 23 mounted on an upper surface of the mounting table 22 to electrostatically adsorb the wafer W; an arm part 24 configured to separate both the electrostatic chuck 23 and the wafer W electrostatically adsorbed to the electrostatic chuck 23 from the mounting table 22; a GCIB irradiation device 25 disposed at a sidewall portion of the processing chamber 21 and configured to approximately horizontally irradiate an oxygen GCIB; and an organic acid storage tank 26 communicating with the processing chamber 21 and configured to store an organic acid, e.g., an acetic acid.

In the planarization processing module 14, the arm part 24 separates the electrostatic chuck 23 from the mounting table 22 such that the electrostatically-adsorbed wafer W is arranged to face the GCIB irradiation device 25. The GCIB irradiation device 25 irradiates the oxygen GCIB toward the wafer W arranged to face the GCIB irradiation device 25.

The organic acid storage tank 26 is coupled to the processing chamber 21 through a communicating pipe 27. A valve 28 is installed in the communicating pipe 27. The communication between the processing chamber 21 and the organic acid storage tank 26 is controlled by opening or closing the valve 28. When the valve 28 is opened, an acetic acid gas evaporated in the organic acid storage tank 26 is introduced into the processing chamber 21 through the communicating pipe 27.

The mounting table 22 is provided with a refrigerant flow path and a heater (both not shown) installed therein. Once the arm part 24 is received in the mounting table 22 and the electrostatic chuck 23 is positioned on the upper surface of the mounting table 22, the electrostatically-adsorbed wafer W may be cooled down or heated.

FIG. 3 is a cross-sectional view schematically showing a configuration of the GCIB irradiation device 25 of FIG. 2.

In FIG. 3, the GCIB irradiation device 25 includes a cylindrical body 29 whose interior is depressurized, a nozzle 30 disposed at one end of the body 29, a plate-shaped skimmer 31, an ionizer 32, an accelerator 33, a permanent magnet 34, and an aperture plate 35. The body 29 is approximately horizontally disposed within the processing chamber 21.

The nozzle 30 is disposed along the central axis of the body 29 and injects an oxygen gas along the central axis. The skimmer 31 is disposed to cover a cross section in the body 29. A central portion of the skimmer 31 is formed to protrude toward the nozzle 30 along the central axis of the body 29. The skimmer 31 includes a fine hole 36 formed at the top of the protruded central portion. Similarly, the aperture plate 35 is disposed to cover another cross section in the body 29 and includes an aperture hole 37 at a position corresponding to the central axis of the body 29. In the other end of the body 29, an aperture hole 38 is formed at a position corresponding to the central axis of the body 29.

The ionizer 32, the accelerator 33 and the permanent magnet 34 are disposed to surround the central axis of the body 29, respectively. The ionizer 32 heats a built-in filament to emit electrons toward the central axis of the body 29. The accelerator 33 generates a potential difference along the central axis of the body 29. The permanent magnet 34 generates a magnetic field in the vicinity of the central axis of the body 29.

In the GCIB irradiation device 25, the nozzle 30, the skimmer 31, the ionizer 32, the accelerator 33, the aperture plate 35 and the permanent magnet 34 are arranged in this order, from one end side (left side in FIG. 3) of the body 29 to the other end side (right side in FIG. 3).

Once the nozzle 30 injects the oxygen gas toward the depressurized interior of the body 29, a volume of the oxygen gas rapidly increases so that the oxygen gas is subjected to a rapid adiabatic expansion, thus rapidly cooling down oxygen molecules. This decreases a kinetic energy so that the oxygen molecules are in close contact with each other by virtue of an intermolecular force (Van der Waals force) exerted between the respective oxygen molecules. Thus, a plurality of oxygen gas clusters 39 which is configured by a plurality of oxygen molecules, is formed.

The skimmer 31 selects, among the plurality of oxygen gas clusters 39, one oxygen gas cluster 39 that moves along the central axis of the body 29 using the fine hole 36. The ionizer 32 allows electrons to collide with the selected oxygen gas cluster 39 that move along the central axis of the body 29, thereby ionizing the selected oxygen gas cluster 39. The accelerator 33 accelerates the ionized oxygen gas cluster 39 toward the other end of the body 29 by virtue of the potential difference. The aperture plate 35 selects, among the accelerated oxygen gas clusters 39, one oxygen gas cluster 39 that moves along the central axis of the body 29 using the aperture hole 37. The permanent magnet 34 changes a travel path of the oxygen gas cluster 39 of a relatively small size (including monomer of the ionized oxygen molecules) by virtue of the magnetic field. In the permanent magnet 34, the oxygen gas cluster 39 of a relatively large size is also affected by the magnetic field. However, since a mass of the relatively large oxygen gas cluster 39 is large, the relatively large oxygen gas cluster 39 continues to move along the central axis of the body 29 while maintaining the travel path thereof by virtue of a magnetic force.

The relatively large oxygen gas cluster 39, which passed through the permanent magnet 34, is discharged outside of the body 29 through the aperture hole 38 formed at the other end of the body 29 such that the relatively large oxygen gas cluster 39 is irradiated toward the wafer W.

Meanwhile, prior to the present disclosure, the present inventors performed an experiment in which an oxygen ion beam and an oxygen GCIB in an acetic acid gas atmosphere are irradiated to a copper substrate having a surface polished by CMP (Chemical Mechanical Polishing) so as to facilitate an etching of copper used as a hard-to-etch metal. The results of the experiment shown that the surface of the copper substrate is etched in either case. In this case, the present inventors have confirmed that a flatness of the copper substrate is improved by the irradiation of the oxygen GCIB rather than the irradiation of the oxygen ion beam. For example, when the flatness of the copper substrate polished by CMP is Ra=0.819 nm, for the irradiation of the oxygen ion beam, the flatness was at a deteriorated level of Ra=1.192 nm, while for the irradiation of the oxygen GCIB, the flatness was at an improved level of Ra=0.511 nm.

Further, the present inventors performed an experiment in which the oxygen GCIB is irradiated toward a substrate made of platinum as the hard-to etch metal, which is obtained by being subjected to a film-forming process by sputtering, and subsequently a crystallization process, in an acetic acid gas atmosphere and in an acetic acid gas-free atmosphere. The results of the experiment show that a flatness of the platinum substrate is improved in either case. For example, when a flatness of a crystallized platinum substrate is Ra=1.85 nm, for the irradiation of the oxygen GCIB in the acetic acid gas-free atmosphere, the flatness was at an improved level of Ra=1.0 nm, while for the irradiation of the oxygen GCIB in the acetic acid gas atmosphere, the flatness was at a further improved level of Ra=0.96 nm.

In addition, the experiment shows that, for the irradiation of the oxygen GCIB in the acetic acid gas-free atmosphere, both platinum and platinum oxide are present on the surface of the platinum substrate, while for the irradiation of the oxygen GCIB in the acetic acid gas atmosphere, only platinum is present on the surface of the platinum substrate.

From the above results, the present inventors obtained findings that even the hard-to-etch metal can be modified into an oxide by the irradiation of the oxygen GCIB, and further, the oxide can be easily removed by the acetic acid gas.

Based on the above findings, the present inventors assumed the reason why the flatness of the hard-to-etch metal can be improved by the oxygen GCIB, as follows.

First, when the oxygen GCIB collides with a surface of a hard-to-etch metal film, a chemical reaction between the metal and the oxygen is facilitated by virtue of the large kinetic energy of the cluster of oxygen molecules, thereby producing a metal oxide on the surface of the metal film. This chemical reaction is preferentially conducted in convex portions of the surface with which the cluster of oxygen molecules collides easily. Even for a hard-to-etch noble metal, a vapor pressure of a noble metal oxide itself is higher than that of other common metal oxides. Further, the vapor pressure is approximately the same as or higher than an internal pressure of the processing chamber. As such, the noble metal is easy to sublimate. Further, since an organic acid having a carboxyl group such as an acetic acid forms a complex with the noble metal to assist the sublimation of the noble metal oxide, the acetic acid gas easily removes the metal oxide.

Meanwhile, the oxygen GCIB, when colliding with the surface of the metal film, preferentially sputters the convex portions protruding from the surface by scattering oxygen molecules from the cluster of oxygen molecules along the surface of the metal film.

That is to say, when the oxygen GCIB is irradiated to the surface of the metal film in an organic acid gas atmosphere, the flatness of the metal film is improved by a synergistic effect of a chemical removal such as the preferential modification of the convex portions of the surface into oxides and the sublimation of the oxides, and a physical removal such as the preferential sputtering of the convex portions of the surface by the oxygen molecules.

Meanwhile, a method of sputtering a surface of a formed metal film using positive ions in plasma is under consideration as a technique to planarize the metal film. However, since the positive ions are dragged into the metal film by a bias voltage, flat portions as well as uneven portions of the surface of the metal film may be etched, which results in deterioration in the flatness of the metal film.

Accordingly, the irradiation of the oxygen GCIB to the surface of the metal film as described above, which can improve the flatness of the metal film without having to use the sputtering by the positive ions in plasma, is very effective as a technique for planarizing a metal film. In addition, an oxidizing gas such as an oxygen gas which oxidizes films constituting an (MTJ) element, degrades the performance of the element, and therefore, is not used in the conventional MRAM manufacturing process. However, as described above, according to the present disclosure, it is possible to use oxygen for the GCIB, and also to use the oxygen by employing the removal of the oxide film by an organic acid.

In this embodiment, based on the aforementioned findings, in the MRAM manufacturing process, as shown in FIG. 4, the oxygen GCIB configured by the oxygen gas clusters 39 is irradiated to a metal film 40 which is formed before an MTJ element is formed, thus planarizing the metal film 40.

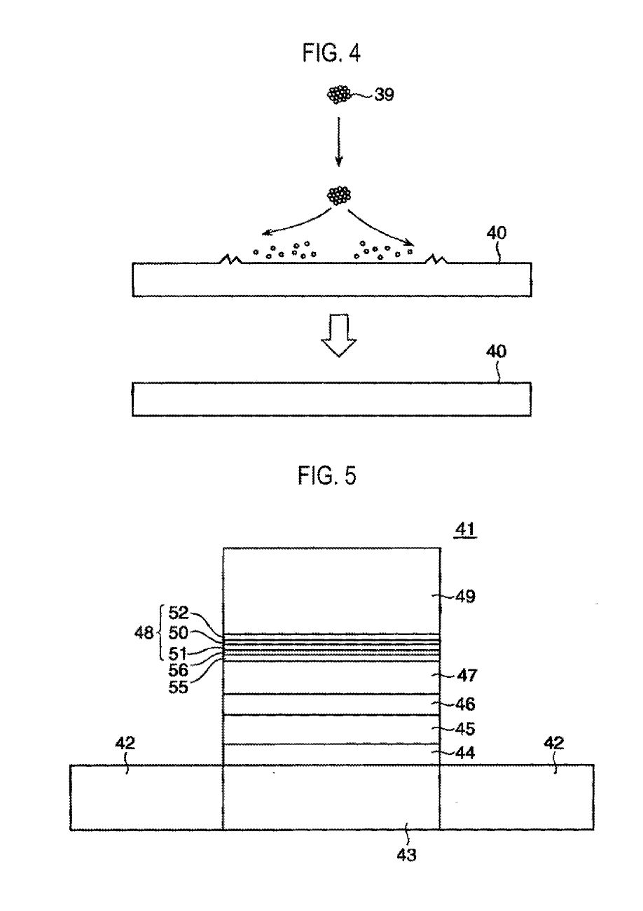

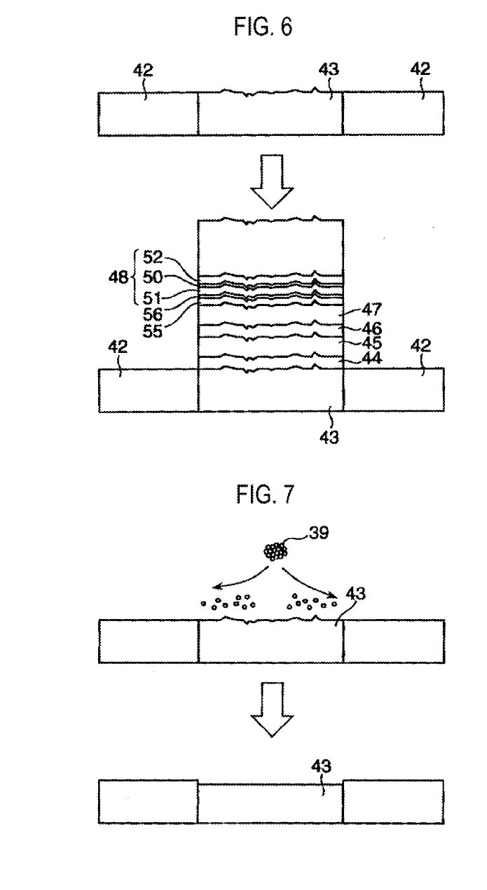

FIG. 5 is a cross-sectional view schematically showing a configuration of an MRAM to which the planarization method according to this embodiment is applied. A plurality of MRAMs is formed on the surface of the wafer W. FIG. 5 shows an MRAM obtained by processing in a stacked structure constituted by a plurality of metal films. Similarly, FIG. 6 and subsequent drawings show states where the MRAM is obtained by processing in the stacked structure. The MRAM is an electronic device having an MTJ element. In general, the MTJ element has a structure in which an oxide film is sandwiched between a ferromagnetic layer used as a fixed layer (with a fixed magnetization direction) and another ferromagnetic layer used as a free layer (with variable magnetization direction). The oxide film is typically made of AlOₓ, MgO or the like. The ferromagnetic layer is made of a NiFe alloy, a CoFe alloy, a CoFeB alloy or the like.

In FIG. 5, an MRAM (or MRAM element) 41 includes: a Cu film 43 embedded in a SiO₂ film 42 that is formed on a silicon base of the wafer W; a Ta film 44 formed on the Cu film 43; a Ru film 45 formed on the Ta film 44; a Ta film 46 formed on the Ru film 45; a PtMn film 47 which is an anti-ferromagnetic layer formed on the Ta film 46; a CoFe thin film 55 formed on the PtMn film 47; a Ru thin film 56 formed on the CoFe thin film 55; an MTJ element 48 formed on the Ru thin film 56; and a Ta film 49 formed on the MTJ element 48. The MTJ element 48 includes a MgO thin film 50 and two CoFeB thin films 51 and 52 facing each other with the MgO thin film 50 interposed therebetween. The Cu film 43 and the Ta film 44 constitute a lower electrode and the Ta film 49 constitutes an upper electrode.

The Cu film 43 is formed by forming a groove in the SiO₂ film 42 by plasma etching or the like, followed by embedding Cu into the groove by plating or the like. Each of the Ta film 44, the Ru film 45, the Ta film 46, the PtMn film 47, the CoFe thin film 55, the Ru thin film 56 and the Ta film 49 is formed by plasma sputtering in the respective film-forming processing module 13. Similarly, each of the MgO thin film 50 and the CoFeB thin films 51 and 52 of the MTJ element 48 is formed by plasma sputtering in the respective film-forming processing module 13.

In the MRAM 41, the thin films 50, 51, 52, 55 and 56, especially, the MgO thin film 50, is planarized to maintain a property of the MTJ element 48. The MgO thin film 50 may have a constant film thickness, e.g., about 1 nm.

Meanwhile, in the manufacturing process of the MRAM 41, for example, as shown in FIG. 6, after the Cu film 43 is formed, a surface of the Cu film 43 is polished by CMP. However, irregularities occur on the surface of the Cu film 43 by CMP or a subsequent plasma exposure applied when etching an insulating film (e.g., a SiCN film) which is formed on the Ta film 44. In addition, the SiCN film is not shown in FIG. 6 because it is removed by etching in the course of the formation of the Cu film 43.

If the Ta film 44 and subsequent films are formed without removing the irregularities of the surface of the Cu film 43, the irregularities of the surface of the Cu film 43 are propagated up to the Ta film 44 and the subsequent films so that each of the thin films 50 to 52 of the MTJ element 48 is not planarized.

Therefore, in this embodiment, after the surface of the Cu film 43 is exposed to plasma so that the irregularities occurs on the surface, and before the Ta film 44 is formed, the wafer W is loaded into the planarization processing module 14. As shown in FIG. 7, the GCIB irradiation device 25 provided within the processing chamber 21 irradiates the oxygen GCIB constituted by the oxygen gas cluster 39 to the Cu film 43 in the acetic acid gas atmosphere. Then, the irregularities of the Cu film 43 are removed by the chemical removal and the physical removal described above, thereby planarizing the surface of the Cu film 43.

Further, since each of the Ta film 44 to the Ta film 46 is formed by plasma sputtering, they are in an amorphous state immediately after being formed. Thereafter, each of the Ta film 44 to the Ta film 46 begins to undergo a polycrystalline growth to reduce the total energy in each of the Ta film 44 to the Ta film 46. This causes a volume shrinkage and deformation, thus generating irregularities on a surface of each of the Ta film 44 to the Ta film 46.

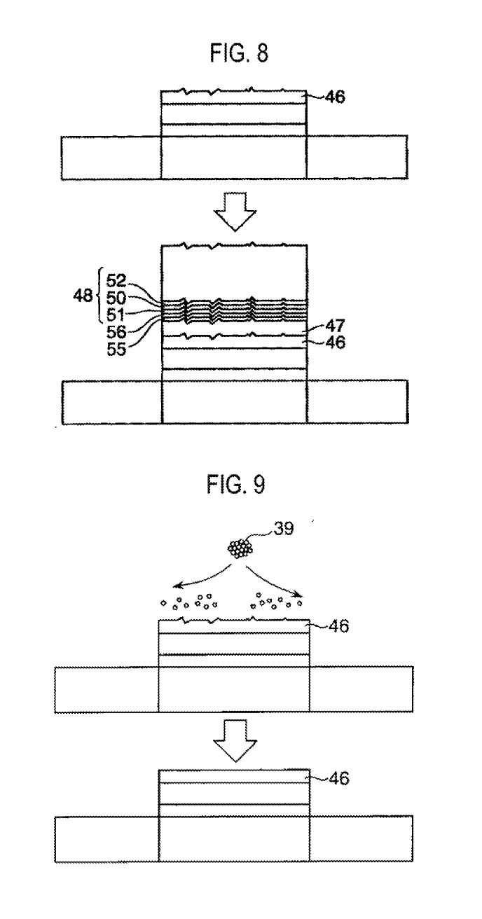

In this case, as shown in FIG. 8, for example, if the PtMn film 47 is formed without removing the irregularities of the surface of the Ta film 46, which occurred by undergoing the polycrystalline growth, the irregularities of the surface of the Ta film 46 are propagated up to the PtMn film 47 to the Ru thin film 56. As such, each of the thin films 50, 51 and 52 of the MTJ element 48 is not planarized.

Therefore, in this embodiment, after the irregularities occur on the surface of the Ta film 46 by the polycrystalline growth, and before the PtMn film 47 is formed, the wafer W is loaded into the planarization processing module 14. As shown in FIG. 9, the oxygen GCIB is irradiated to the Ta film 46 in the acetic acid gas atmosphere within the processing chamber 21. Then, the irregularities of the Ta film 46 are removed by the chemical removal and the physical removal described above, thereby planarizing the surface of the Ta film 46. In some embodiments, any one of the Ta film 44 to the Ta film 46 may be planarized by the oxygen GCIB. Alternatively, all of the Ta film 44 to the Ta film 46 may be planarized by the oxygen GCIB.

Further, since the PtMn film 47 is formed by plasma sputtering, the PtMn film 47 is in an amorphous state immediately after being formed. Thereafter, the PtMn film 47 begins to undergo the polycrystalline growth so that irregularities occur on the surface of the PtMn film 47.

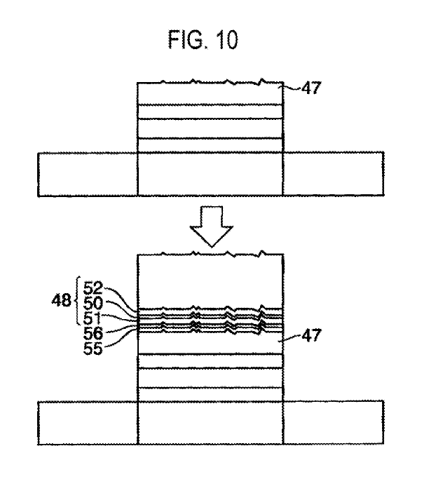

In this case, as shown in FIG. 10, if the MTJ element 48 is formed without removing the irregularities of the surface of the PtMn film 47, which occurred by undergoing the polycrystalline growth, the irregularities of the surface of the PtMn film 47 are propagated up to the CoFe thin film 55, the Ru thin film 56 and the CoFeB thin film 51. As such, the MgO thin film 50 is not planarized.

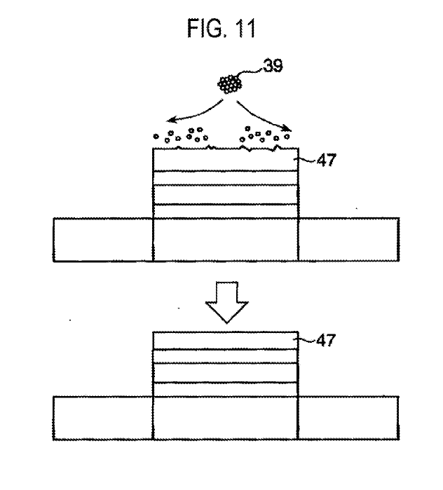

Therefore, in this embodiment, after the irregularities occur on the surface of the PtMn film 47 by the polycrystalline growth, and before the MTJ element 48 is formed, the wafer W is loaded into the planarization processing module 14. Thereafter, as shown in FIG. 11, the oxygen GCIB is irradiated to the PtMn film 47 in the acetic acid gas atmosphere within the processing chamber 21. Then, the irregularities of the PtMn film 47 are removed by the chemical removal and the physical removal described above, thereby planarizing the surface of the PtMn film 47.

In addition, the CoFe thin film 55 and the Ru thin film 56 are in an amorphous state immediately after being formed so that irregularities may occur by undergoing the polycrystalline growth. However, since the CoFe thin film 55 and the Ru thin film 56 are thinner than other metal films, the irregularities that occur are not so large that they hardly affect a flatness of the MgO thin film 50. Further, since the CoFe thin film 55 and the Ru thin film 56 are extremely thin, they are hard to planarize. Therefore, in planarizing the MgO thin film 50, the planarization of the PtMn film 47 is more effective than the planarization of the CoFe thin film 55 and the Ru thin film 56.

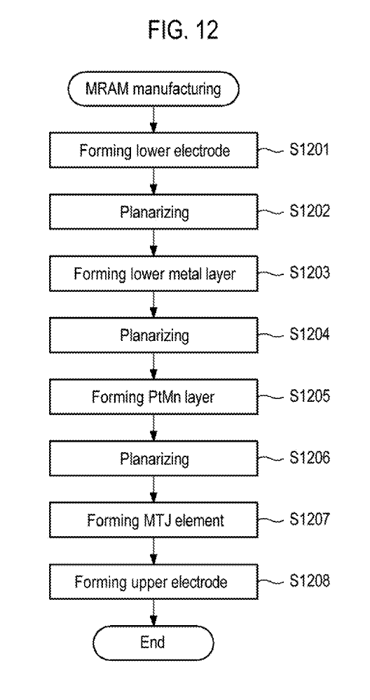

FIG. 12 is a flowchart of the MRAM manufacturing process to which the planarization method according to this embodiment is applied. The MRAM manufacturing process is executed by the control part 20 which controls operations of respective components of the substrate treatment system 10 according to a predetermined program.

In FIG. 12, first, the wafer W is loaded into the film-forming processing module 13 where the Cu film 43 is embedded in the SiO₂ film 42. Subsequently, the wafer W is loaded into a polishing module (not shown) where a surface of the Cu film 43 is polished by CMP, thus forming the polished Cu film 43 as a portion of the lower electrode (step S1201).

Thereafter, the wafer W is loaded into the planarization processing module 14 where the wafer W is electrostatically adsorbed to the electrostatic chuck 23. The electrostatically-adsorbed wafer W is cooled down to, e.g., room temperature or below. The acetic acid gas evaporated from the organic acid storage tank 26 is introduced into the processing chamber 21 at a flow rate of, e.g., 5.3×10⁻³ Pa. The wafer W, which is electrostatically adsorbed to the electrostatic chuck 23, is arranged to face the GCIB irradiation device 25 by the arm part 24. The GCIB irradiation device 25 irradiates an oxygen GCIB toward the wafer W to planarize the Cu film 43 (step S1202). At this time, the arm part 24 moves the electrostatic chuck 23 in a vertical direction and a depth direction in FIG. 2 such that the entire surface of the wafer W is scanned by the oxygen GCIB. In some embodiments, in order to facilitate the planarization of the Cu film 43 by the oxygen GCIB, the wafer W may be arranged to be inclined with respect to the oxygen GCIB instead of being arranged to directly face the oxygen GCIB.

Thereafter, the wafer W is loaded into the film-forming processing module 13 where the Ta film 44 is formed, and subsequently, the Ru film 45 and the Ta film 46 are formed on the Ta film 44 as a lower metal layer (step S1203). Each of the Ta film 44, the Ru film 45 and the Ta film 46 may be formed by the same film-forming processing module 13, or by different film-forming processing modules 13.

As the Ta film 44, the Ru film 45 and the Ta film 46 undergo polycrystalline growth, irregularities occur on respective surfaces of the Ta film 44, the Ru film 45 and the Ta film 46. Once the polycrystalline growth progresses to some extent, the wafer W is loaded into the planarization processing module 14 where, like step S1202, the oxygen GCIB is irradiated to the wafer W to planarize each of the Ta film 44, the Ru film 45, and the Ta film 46 (step S1204).

Subsequently, the wafer W is loaded into the film-forming processing module 13 where the PtMn film 47 (as the anti-ferromagnetic layer) is formed (step S1205). Even in the surface of the PtMn film 47, irregularities occur by undergoing the polycrystalline growth. As such, after the polycrystalline growth progresses to some extent, the wafer W is loaded into the planarization processing module 14 where, like step S1202, the oxygen GCIB is irradiated to the wafer W, thus planarizing the PtMn film 47 (step S1206).

Thereafter, the wafer W is loaded into the film-forming processing module 13 where the CoFe thin film 55 and the Ru thin film 56 are formed. Further, the CoFeB thin film 51, the MgO thin film 50 and the CoFeB thin film 52 are formed on the Ru thin film 56 in that order, thus forming the MTJ element 48 on the PtMn film 47 (step S1207).

Subsequently, the wafer W is loaded into another film-forming processing module 13 where the Ta film 49 is formed on the MTJ element 48, thus forming an upper electrode (step S1208). In this way, the MRAM manufacturing process is terminated.

According to the MRAM manufacturing process of FIG. 12, the oxygen GCIB is irradiated to each of the formed metal films 43 to 47 before the formation of the MTJ element 48 on the wafer W. When the oxygen GCIB is irradiated to each of the metal films 43 to 47, even if each of the metal films 43 to 47 is constituted by, e.g., a noble metal, the surface of each of the metal films 43 to 47 is oxidized such that they are modified into a relatively easy-to-sublimate oxide. Further, when the cluster of oxygen molecules in the GCIB collides with the surface of each of the metal films 43 to 47, the oxygen molecules are scattered along the surface of each of the metal films 43 to 47, thus sputtering the convex portions protruding from the respective surfaces. That is to say, the convex portions of the surface of each of the metal films 43 to 47 are removed by the chemical removal and the physical removal. In this way, it is possible to reliably planarize each of the formed metal films 43 to 47 before the formation of the MTJ element 48 of the MRAM.

In addition, in the MRAM manufacturing process of FIG. 12, it is possible to improve a planarization rate using a combination of the chemical removal and the physical removal. Further, since there is no need to facilitate a chemical reaction by heating, it is possible to planarize the wafer W at a relatively low temperature. Therefore, for example, it is possible to suppress the property of the MTJ element 48 from being changed by heating.

Further, in the MRAM manufacturing process of FIG. 12, since the sputtering is not performed by positive ions in plasma, there is no concern that a flatness of each of the metal films 43 to 47 is deteriorated. In addition, since a halogen gas is not used, there is no need to perform a cleaning process of removing the halogen gas after the planarization.

In the MRAM manufacturing process of FIG. 12 described above, the oxygen GCIB is irradiated to each of the metal films 43 to 47 in the acetic acid gas atmosphere. As the acetic acid easily removes metal oxides, the convex portions of the surface of each of the metal films 43 to 47 which are modified into oxides by the oxygen GCIB, can be reliably removed. Further, the convex portions are sputtered by the oxygen molecules, which makes it possible to remove metal oxides adhering to the inner wall and the like of the processing chamber 21 by scattering. This reduces cleaning times of the processing chamber 21, thus improving an operating rate of the substrate treatment system 10.

Meanwhile, the oxides may remain on the surface of each of the metal films 43 to 47. This oxidizes a portion of the CoFeB thin films 51 and 52 which are to be formed later, thus influencing the property of the MTJ element 48. However, the oxides existing on the surface of each of the metal films 43 to 47 are removed by the acetic acid gas, which makes it possible to prevent the oxidation of the portion of the CoFeB thin films 51 and 52, thus preventing the property of the MTJ element 48 from being influenced.

Further, in the MRAM manufacturing process of FIG. 12 described above, the electrostatically-adsorbed wafer W is cooled down to the room temperature or below, thus improving an adsorption coefficient of the acetic acid gas with respect to the wafer W. Therefore, the oxides of each of the metal films 43 to 47 is efficiently removed by the acetic acid gas. Meanwhile, if the acetic acid adsorbed to the wafer W remains until a subsequent process, e.g., a film-forming process using sputtering, the acetic acid has an influence on the subsequent process. Accordingly, after the irradiation of the oxygen GCIB, it is preferable in some embodiments to vaporize and remove the acetic acid from the wafer W by heating the wafer W through the heater of the mounting table 22.

In the MRAM manufacturing process of FIG. 12 described above, the oxygen GCIB has been described to be irradiated in the atmosphere of the acetic acid gas used as the organic acid, but is not limited thereto. As an example, when the metal film includes Pt or Ru as a noble metal, oxides (e.g., PtO, PtO₂, RuO, or RuO₂) of such a noble metal has high vapor pressure so that they are easy to sublimate. As such, the acetic acid gas atmosphere is not essential in the irradiation of the oxygen GCIB.

In addition, in the MRAM manufacturing process of FIG. 12 described above, while the metal films 43 to 47 has been described to be planarized by irradiating the oxygen GCIB to each of the metal films 43 to 47 formed below the MTJ element 48, it is not necessary to planarize all of the metal films 43 to 47. As an example, even though only at least one of the metal films 43 to 47 is planarized, the planarization of the MgO thin film 50 in the MTJ element 48 can be expected. In particular, if the oxygen GCIB is irradiated to only the PtMn film 47 that is close to the MTJ element 48 to perform the planarization, even if the irregularities that occur by the polycrystalline growth and the irregularities of the surface of each of the metal films 43 to 46 formed below the PtMn film 47 are propagated up to the surface of the PtMn film 47, it is possible to remove any irregularities at one time, thus improving the efficiency of the planarization. However, when the oxygen GCIB is irradiated to the PtMn film 47 over a long period of time, Mn escapes from the PtMn film 47, thus causing a loss of magnetism. To address this, in some embodiments, a Mn-rich PtMn thin film as a sacrificial layer may be formed on the PtMn layer 47.

Moreover, although the CoFeB thin film 51 formed directly below the MgO thin film 50 may be planarized by the irradiation of the oxygen GCIB, it is hard to planarize the CoFeB thin film 51 since the CoFeB thin film 51 is very thin. Therefore, when planarizing the CoFeB thin film 51, it is preferable in some embodiments to planarize other metal films together.

Next, a planarization method and a substrate treatment system according to a second embodiment of the present disclosure will be described.

The second embodiment has basically the same configuration and operation as in the first embodiment described above except that the substrate treatment system according to the second embodiment further includes an annealing module. Therefore, description of the configuration and operation that overlap with the first embodiment will be omitted, and differences in configuration and operation will be described.

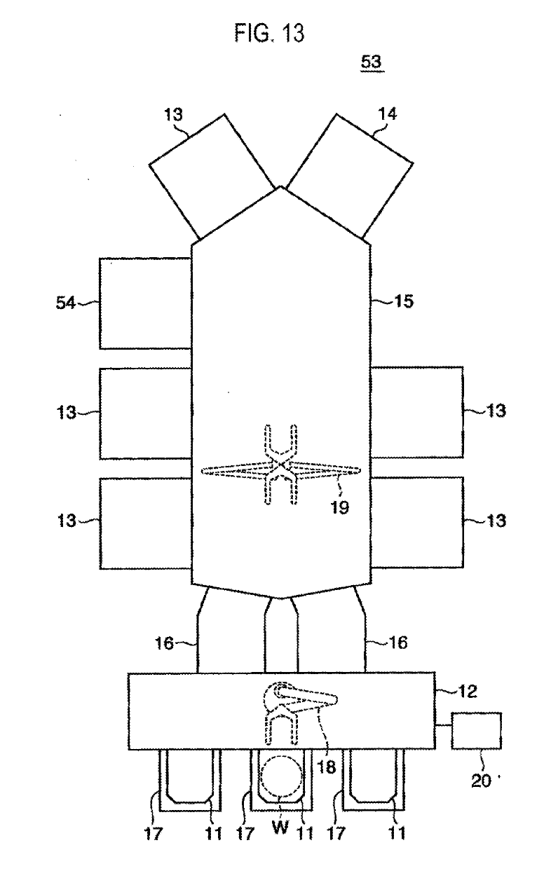

FIG. 13 is a plan view schematically showing a configuration of the substrate treatment system according to the second embodiment.

In FIG. 13, unlike the substrate processing system 10, a substrate treatment system 53 further includes an annealing module 54 (as a heating processing chamber) in addition to the film-forming processing modules 13 and the planarization processing module 14. The annealing module 54 has a built-in lamp heater or the like (not shown) to heat the wafer W loaded thereinto.

Each of the metal films 43 to 47, which is formed by sputtering and is in an amorphous state, undergoes the polycrystalline growth so that irregularities occur on the surface of each of the metal films 43 to 47. The polycrystalline growth progresses at a relatively slow speed. In this situation, when each of the metal films 43 to 47 is planarized by the irradiation of the oxygen GCIB while the polycrystalline is not fully grown, there is a possibility that each of the metal films 43 to 47 still undergo the polycrystalline growth even after the planarization, thereby occurring irregularities on the planarized surfaces.

In this embodiment, to address the above, each of the metal films 43 to 47 is heated to facilitate the polycrystalline growth, thus saturating the poly-crystallization of each of the metal films 43 to 47 before the planarization process by the irradiation of the oxygen GCIB.

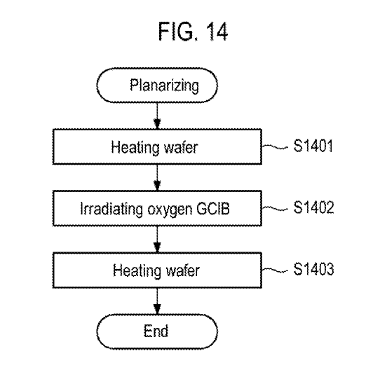

FIG. 14 is a flowchart of the planarization method according to the second embodiment. This method is applied to steps S1202, S1204 and S1206 in the MRAM manufacturing process of FIG. 12.

In FIG. 14, first, the wafer W is loaded into the annealing module 54 where the wafer W is heated by the lamp heater. At this time, in any one of the metal films 43 to 47 being in an amorphous state (hereinafter, simply referred to as “metal film”), a polycrystalline growth is facilitated to saturate the poly-crystallization (step S1401). In addition, when the PtMn film 47 is heated, the heating is performed in some embodiments at a Curie temperature of PtMn or below to prevent a loss of the magnetism of the PtMn film 47.

Subsequently, the wafer W is loaded into the planarization processing module 14 where the wafer W is electrostatically adsorbed to the electrostatic chuck 23 and the acetic acid gas evaporated from the organic acid storage tank 26 is introduced into the processing chamber 21. Further, the wafer W, which is electrostatically adsorbed to the electrostatic chuck 23, is arranged to face the GCIB irradiation device 25 by the arm part 24. The GCIB irradiation device 25 irradiates the oxygen GCIB toward the wafer W to planarize the metal film (step S1402). At this time, since the poly-crystallization of the metal film has been saturated, a polycrystalline growth does not occur in the planarized metal film, which prevents irregularities from occurring in the planarized surfaces.

Thereafter, the wafer W is loaded again into the annealing module 54 where the wafer W is heated by the lamp heater. At this time, the acetic acid adsorbed to the wafer W is vaporized and removed (step S1403). In this way, the planarization method is terminated.

According to the planarization method of FIG. 14, the wafer W is heated before the irradiation of the oxygen GCIB to the metal film so that the poly-crystallization of the metal film can be saturated. Thus, it is possible to prevent the flatness of the metal film from being again decreased by progressing the polycrystalline growth in the metal film which is planarized by the irradiation of the GCIB.

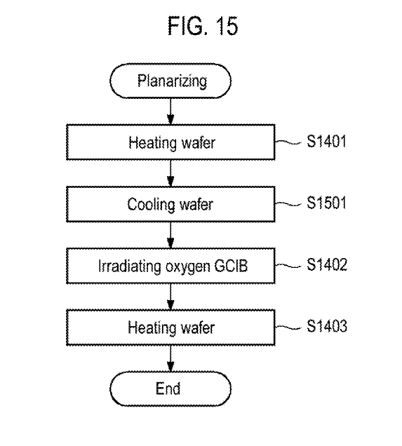

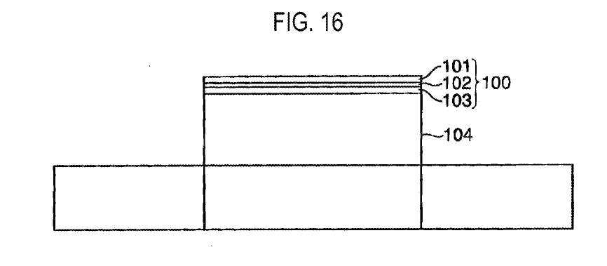

In some embodiments, in order to improve an adsorption coefficient of the acetic acid gas with respect to the wafer W, as shown in FIG. 15, after the wafer W is heated in step S1401 and before the planarization process is performed by the irradiation of the oxygen GCIB in step S1402, the wafer W is loaded into the planarization processing module 14 where the wafer W is electrostatically adsorbed to the electrostatic chuck 23 and is cooled down to, e.g., room temperature or below (step S1501).

Thus, since the wafer W is not heated after the wafer W is cooled down and before the planarization process is performed by the irradiation of the oxygen GCIB, it is possible to improve the adsorption coefficient of the acetic acid gas with respect to the wafer W in the planarization process.

In the planarization method of FIG. 14 described above, the heating process for saturating the poly-crystallization of the metal film has been described to be performed in the annealing module 54, but may be performed by the heater provided in the mounting table 22 of the planarization processing module 14.

Although the present disclosure has been described with reference to the above embodiments, the present disclosure is not limited to the above embodiments.

The flowchart of the MRAM manufacturing process shown in FIG. 12 and the planarization method shown in FIG. 14 may be applied in manufacturing an MRAM having a configuration other than the configuration shown in FIG. 5, as long as a metal layer exists close to the MTJ element 48.

As an example, in terms of an electrical circuitry configuration, another MRAM having a structure in opposition to the MRAM 41 of FIG. 5 may be used. In order to manufacture another such MRAM, for example, each step of the MRAM manufacturing process shown in FIG. 12 is performed in the reverse order. In this case, after step S1208, a planarization process similar to step S1202 is performed to planarize the Ta film 49, and subsequently, step S1207 is performed. Thus, it is possible to planarize each thin film that constitutes the MTJ element 48, especially, the MgO thin film 50. Further, in this case, the planarization processes of steps S1206, S1204 and S1202 are unnecessary.

In addition, the noble metal constituting the lower metal layer of the MRAM is not limited to Ru and Ta, and another noble metal such as Pt may be used.

Further, the organic acid gas that is introduced into the processing chamber 21 is not limited to the acetic acid gas. As an example, a formic acid gas or a chloroacetic acid gas which is an organic acid (carboxylic acid) having a carboxyl group may be introduced into the processing chamber 21.

Moreover, the objective of the present disclosure may be achieved by providing a memory medium that stores a program code of a software for implementing respective functions of the above embodiments to a computer, e.g., the control part 20, and by allowing a central processing unit of the control part 20 to read and execute the program code stored in the memory medium.

In such a case, the program code itself which read from the memory medium implements the respective functions of the above embodiments, and the program code and the memory medium that stores the program code constitute the present disclosure.

In addition, examples of the memory medium for providing the program code may include RAM, NV-RAM, a floppy (registered mark) disk, a hard disk, an optomagnetic disk, an optical disk such as CD-ROM, CD-R, CD-RW and DVD (DVD-ROM, DVD-RAM, DVD-RW, DVD+RW), a magnetic tape, a nonvolatile memory card, and other ROMs, which are capable of storing the program code. Alternatively, the program code may be provided to the control part 20 by downloading from another computer and data base (both not shown) which are connected to an internet, a commercial network, a local area network or the like.

Further, the respective functions of the above embodiments may be implemented by executing the program code which is read by the control part 20, and by allowing an OS (operating system) running on the CPU to execute a portion or all of the actual processes based on an instruction of the program code.

Further, the respective functions of the above embodiments may be implemented by writing the program code read from the memory medium into a memory provided in a function expansion board inserted into the control part 20 or a function expansion unit connected to the control part 20, and by allowing a CPU or the like provided in the function expansion board or the function expansion unit to execute a portion or all of the actual processes based on an instruction of the program code.

The program code may be configured in a form such as an object code, a program code executed by an interpreter, a script data provided to the OS, or the like.

What is claimed is:

1. A planarization method, comprising:
irradiating an oxygen GCIB (gas cluster ion beam) to a metal film formed on a substrate, the metal film being formed before an MTJ (Magnetic Tunnel Junction) element of an MRAM (Magnetoresistive Random Access Memory) is formed.

2. The planarization method of claim 1, wherein the oxygen GCIB is irradiated to the metal film in an organic acid atmosphere.

3. The planarization method of claim 2, wherein the substrate is heated after the irradiation of the oxygen GCIB to the metal film.

4. The planarization method of claim 1, wherein a plurality of metal films is formed before the MTJ element is formed on the substrate,
after forming one metal film of the plurality of metal films and before forming another metal film that covers the one metal film, the oxygen GCIB is irradiated to the one metal film.

5. The planarization method of claim 1, wherein the oxygen GCIB is irradiated to the metal film that is formed at least immediately before the MTJ element is formed.

6. The planarization method of claim 1, wherein the substrate is heated before the irradiation of the oxygen GCIB to the metal film.

7. A substrate treatment system, comprising:
a film-forming processing chamber configured to form a metal film; and
a GCIB irradiation processing chamber configured to irradiate an oxygen GCIB,
wherein the film-forming processing chamber forms the metal film on a substrate before an MTJ element of an MRAM is formed, and
the GCIB irradiation processing chamber irradiates the oxygen GCIB to the formed metal film before the MTJ element is formed.

8. The substrate treatment system of claim 7, further comprising: a heating processing chamber configured to heat the substrate,
wherein the heating processing chamber heats the substrate after the formation of the metal film and before the irradiation of the oxygen GCIB to the metal film.

9. An MRAM manufacturing method, comprising:
a lower electrode formation step of forming a lower electrode;
a lower metal layer formation step of forming a lower metal layer on the lower electrode;
an anti-ferromagnetic layer formation step of forming an anti-ferromagnetic layer on the lower metal layer;
an MTJ element formation step of forming an MTJ element on the anti-ferromagnetic layer; and
an upper electrode formation step of forming an upper electrode on the MTJ element;
the method further comprising a planarization step that is performed at least one of between the lower electrode formation step and the lower metal layer formation step, between the lower metal layer formation step and the anti-ferromagnetic layer formation step, and between the anti-ferromagnetic layer formation step and the MTJ element formation step,
wherein in the planarization step includes irradiating an oxygen GCIB to a formed metal film.

10. An MRAM manufacturing method comprising:
a lower electrode formation step of forming a lower electrode;
a planarization step of planarizing the lower electrode;
an MTJ element formation step of forming an MTJ element on the planarized lower electrode;
an anti-ferromagnetic layer formation step of forming an anti-ferromagnetic layer on the MTJ element;
an upper metal layer formation step of forming an upper metal layer on the anti-ferromagnetic layer; and
an upper electrode formation step of forming an upper electrode on the upper metal layer,
wherein the planarization step includes irradiating an oxygen GCIB to a formed metal film.

11. An MRAM element comprising at least an MTJ element formed on a metal film, wherein a flatness of the metal film is Ra=1.0 nm or less.
